(19) United States
(12) Patent Application Publication
(10) Pub. No.: US 2006/0134562 A1
(43) Pub. Date: Jun. 22, 2006

(54) Method of forming micro-pattern

(75) Inventors: Chin-Tai Chen, Kaohsiung (TW); Ching-Long Chiu, Tainan (TW); Ji-Bin Horng, Tainan (TW)

Correspondence Address: QUINTERO LAW OFFICE, 1617 BROADWAY, 3RD FLOOR, SANTA MONICA, CA, 90404, US

(73) Assignee: INDUSTRIAL TECHNOLOGY RESEARCH INSTITUTE, HSINCHU (TW)

(21) Appl. No.: 11/078,044

(22) Filed: Mar. 11, 2005

(30) Foreign Application Priority Data
Dec. 22, 2004 (TW) TW93140029

(51) Int. Cl. G03F 7/00

(52) U.S. Cl. 430/322; 430/394

(57) ABSTRACT

A method of forming a micro pattern. The method comprises the following steps: providing a substrate; forming a first micro-fluid layer of photo resistant material on the substrate; providing a first photo mask; and exposing the first micro-fluid layer to light via the first photo mask to form a micro pattern. The dimension of the first micro-fluid layer is larger than that of the micro pattern.

### BACKGROUND OF THE INVENTION

The invention is related to a method of forming a micro pattern, and in particular to a method combining photolithography and micro-fluidic deposition to fabricate a micro pattern.

U.S. Pat. No. 5,453,876 discloses a method of forming a micro pattern based on photolithography technology, wherein a micro lens array is made by exposing a photo resist via a mask. Although the photolithography technology has high precision, the height of the photo resist is, however, limited due to exposure energy.

U.S. Pat. No. 5,644,431 discloses a method of fabricating a micro-lens sheet that employs an extrusion and molding technology. Although this method offers a high production rate, the size and precision is limited. Additionally, a predetermined mask or mold is required in the described methods such that the location and arrangement of the pattern is limited and the cost is increased.

CANON Inc. disclosed an inkjet method using inkjet heads spreading ink with red, green and blue colors on a transparent substrate (U.S. Pat. No. 5,593,757), a transparent substrate with ink receiver (U.S. Pat. No. 5,593,757) or a transparent substrate with ink receiver and hydrophobic region (U.S. Pat. No. 5,716,740). In the transparent substrate, because the ink drops easily move thereon, color mixing can occur. In the transparent substrate with ink receiver, diffusion of ink drops forms non-uniform color regions thereon, causing poor light filtering. When the ink drop is large enough, color mixing can occur due to diffusion in the ink receiver. In the transparent substrate with hydrophobic region, the non-uniform color region caused by diffusion still exists.

The Industrial Technology Research Institute (ITRI) of Taiwan has developed a micro fluidic method disclosed in US patent publication No. 20030118921A1. In this method, a plurality of micro stripped and deep channels are formed on a transparent substrate to serve as high wall boundaries. Color fluids are filled into the channels with a micro-fluid jetting device to form color layers.

In the inject technology, as the micro droplets have drop-on-demand (DOD) and coating-like deposition, it is applied to a circuit such as a flip-chip bonding circuit board, transistors such as thin-film transistors, and displays such as LCD color filters. In the described applications, the micro pattern has an uneven film thickness caused by the fluidic nature of the micro fluid. This often results in the problems in the inkjet process.

### SUMMARY OF THE INVENTION

A preferred embodiment of the method of forming a micro pattern according to the invention comprises the following steps: providing a substrate; forming a first micro-fluid layer of photo resist material on the substrate; providing a first photo mask; and exposing the first micro-fluid layer to illuminate via the first photo mask to form a micro pattern. The dimension of the first micro-fluid layer is larger than that of the micro pattern.

The preferred embodiment further comprises the following steps: forming a gap in the first micro-fluid layer; forming a second micro-fluid layer of photo resistance material in the gap; providing a second photo mask; and exposing the second micro-fluid layer to illuminate via the second photo mask.

The first micro-fluid layer can be configured in a line pattern or a frame pattern by continuously disposing a plurality of partially overlapping micro-fluid drops on the substrate.

Another preferred embodiment of method of forming a micro pattern comprises the following steps: providing a substrate; forming a plurality of micro-fluid layers corresponding to various photo resist materials with different color in different positions on the substrate; providing a photo mask; and exposing the micro-fluid layers to illuminate via the photo mask to form micro patterns.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1a is a top view of a droplet film;

FIG. 1b is a side view of a droplet film;

FIGS. 2a and 2b depict a method of forming a micro pattern with single droplet according to the invention;

FIGS. 3a to 3d depict a method of forming a micro pattern with single droplet according to the invention;

FIGS. 4a to 4d depict a method of forming a micro pattern by droplet lithography and micro-fluidic deposition according to the invention;

FIG. 5 depicts a method of forming a micro pattern with dual droplets according to the invention;

FIGS. 6a and 6b depict a method of forming a micro pattern with multiple droplets according to the invention;

FIGS. 7a and 7b depict a method of forming a micro pattern with multiple droplets according to the invention; and

FIGS. 8a to 8c depict a method of forming a colorful micro pattern with alternatively disposed color droplets.

### DETAILED DESCRIPTION OF THE INVENTION

When droplet liquid flow is spayed on a solid surface, the interfacial lines between the liquid, solid and gas state has a specific contact angle when the droplet is in equilibrium. The correlation is shown as follows:
γ_{LV} cos(θ)=γ_{SV}−γ_{LS} and
ΔP=ρgt=γ_{LS}(1/r₁+1/r₂)
wherein θ is the contact angle, γ_{LV}, γ_{SV} and γ_{LS} are the surface energies of the liquid-gas interface, solid-gas interface and liquid-solid interface respectively, ΔP is the pressure difference between inside the liquid and outside the liquid, ρ is the liquid density, g is the acceleration of gravity, t is the maximum height of the liquid, and r1 and r2 represent the curvature radius of the liquid surface contacting the solid surface in two directions. When the γ_{LV}, γ_{SV} and γ_{LS} are given, contact angle θ is obtained. Provided that the liquid has the same curvature radius, r1=r2=r, and liquid volume (V), density and acceleration of gravity are given, t and r can be determined by the equation V=π/6×[t³+3r²]. The described correlation can be employed to determine the position and pattern of liquid drops on a solid surface.

When a liquid drop is sprayed on the solid surface, the liquid drop is in equilibrium and changes from liquid state to solid state to form the micro pattern. The time of phase change can be several seconds to several minutes. Although the radius of the liquid drop can be substantially unchanged (Δr/r 0), the solidified liquid drop comprises a flat middle portion and a concave edge portion caused by thermal-capillary flow effect and diffusion balance. The ratio of the flat middle portion to the concave edge portion depends on the concentration of the solidified liquid drop. The photolithography can be used to modify the shape of the solidified liquid drop to obtain a precise pattern and uniform thickness.

In addition, the invention employs interlaced deposition to jet different liquid drops on a substrate. The adjacent liquid drops are jetted onto the substrate at different times such that the micro patterns formed by the liquid drops do not interfere with each other during either the static equilibrium or the phase change.

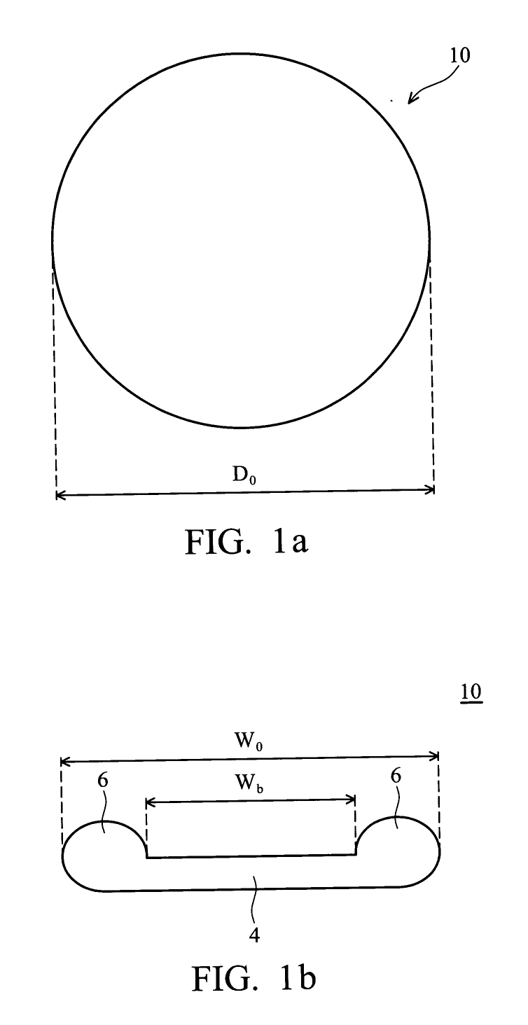

To adequately describe the method of the invention, the structure of a liquid drop is first described. FIG. 1a depicts a droplet film 10 formed by a single micro-fluid droplet. FIG. 1b is a side view of the droplet film 10. Droplet film 10 is a dry film and comprises a flat middle portion 4 and a concave edge portion 6. The diameter of the droplet film 10 is D₀, the width of the solidified droplet film 10 is W₀, and the width of the flat middle portion 4 is W_{b}, the height of the flat middle portion 4 is h_{b}, and the height of the concave edge portion 6 is h₀. The diameter D₀ is equal to the width W₀, and the width W_{b} is smaller than the width W₀. The structure of a droplet film can be featured by the following equations:
D₀=W₀
W_{b}<W₀ Eq. 1

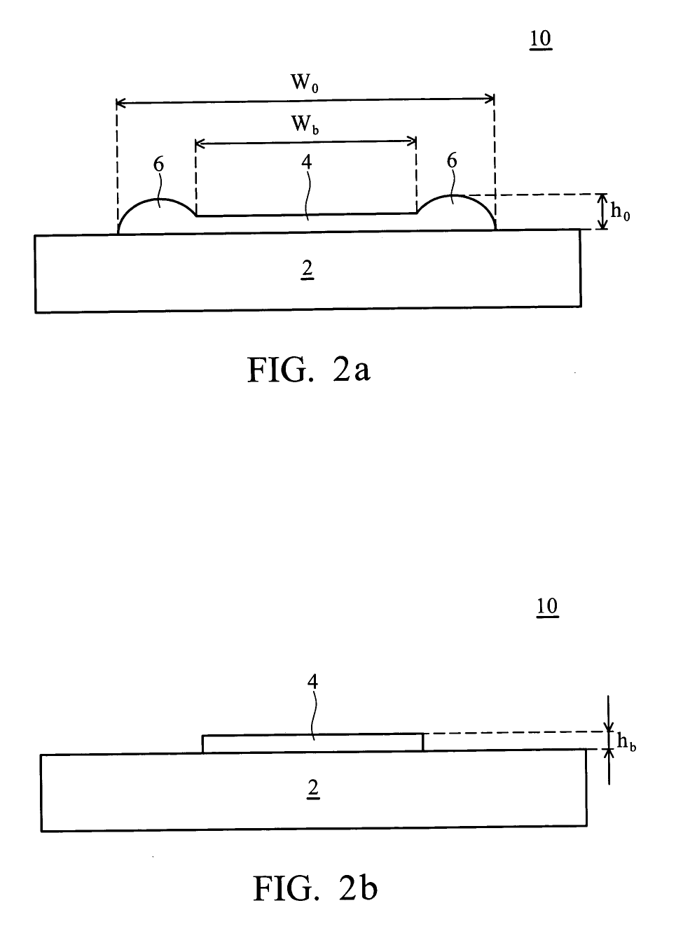

The method of forming a uniform thin film on a substrate from a single droplet is described in FIGS. 2a and 2b. A micro droplet is deposited on a substrate 2 to form a droplet film 10. The micro droplet is evaporated to form a droplet film 10 comprising a flat middle portion 4 and a concave edge portion 6 due to thermal-capillary flow and diffusion balance. In other words, h₀ is larger than h_{b}. The following equation shows the correlation of the heights:
H_{b}<h₀ Eq. 2

The diameter D₀ and the width W₀ usually range from several 10 μm to several 100 μm, and the height h₀ and h_{b} probably range from 1 μm to several micrometers. The ratio of the flat middle portion to the concave edge portion 6 depends on the concentration of the droplet film 10.

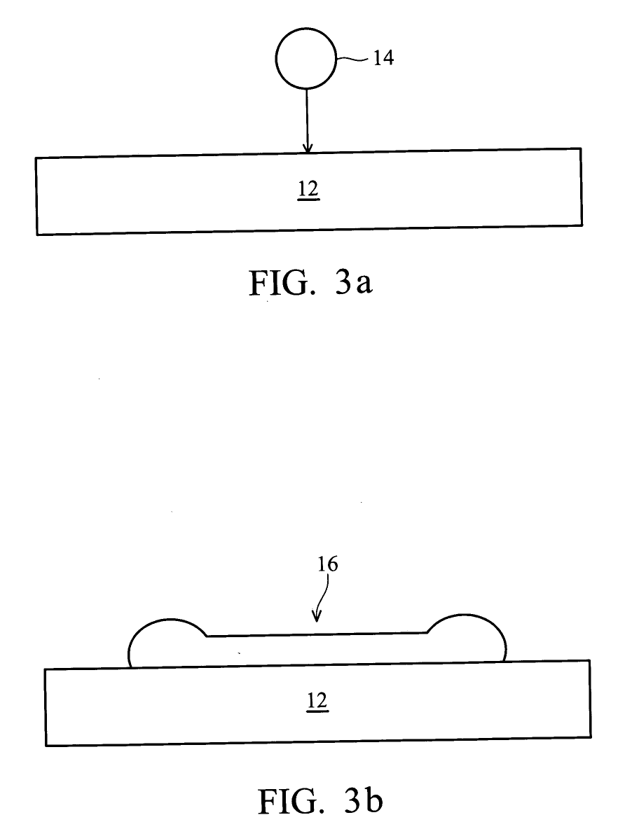

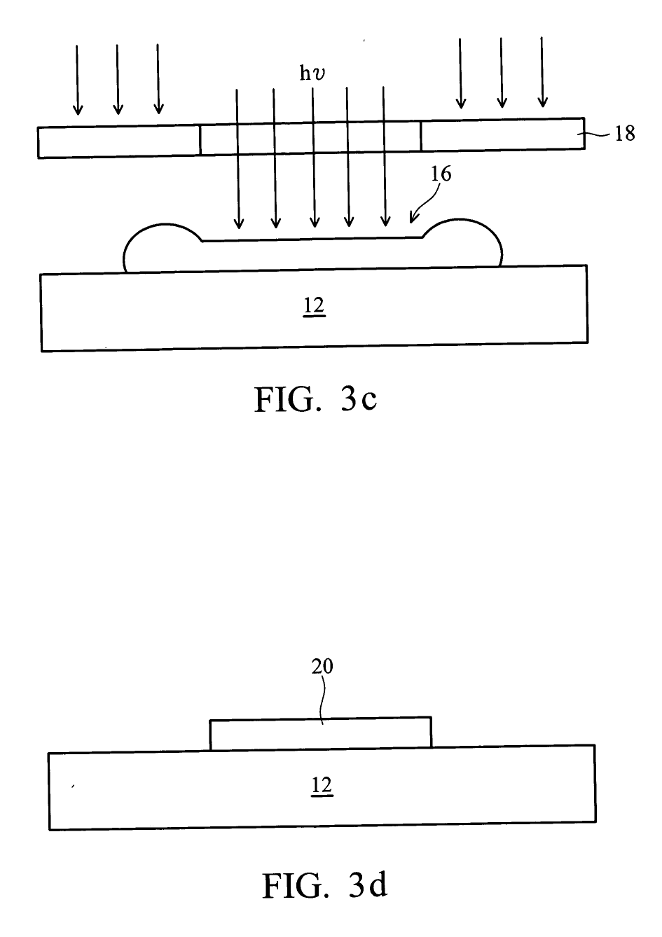

To achieve precise patterning of a micro droplet, lithography patterning (LP) and micro-fluidic deposition (MD) are applied in the invention as shown in FIGS. 3a to 3d. The micro-fluidic deposition employs a droplet actuator according to an inkjet-based technology to deposit micro droplets on a substrate. The method of forming a micro pattern comprises the following steps:

Step 1: A clean substrate 12 is provided, and micro fluid 14 is deposited on the substrate 12 as shown in FIG. 3a.

Step 2: The deposited micro fluid 14 is solidified into a dry film (a first micro fluid layer 16) as shown in FIG. 3b. The first micro fluid layer 16 is a hydrophilic photo resist with a thickness of several hundreds nanometers to several micrometers.

Step 3: The first micro fluid layer 16 is exposed to light, such as I-line 365 nm/5 mW mercury light, via a pattern mask as shown in FIG. 3c.

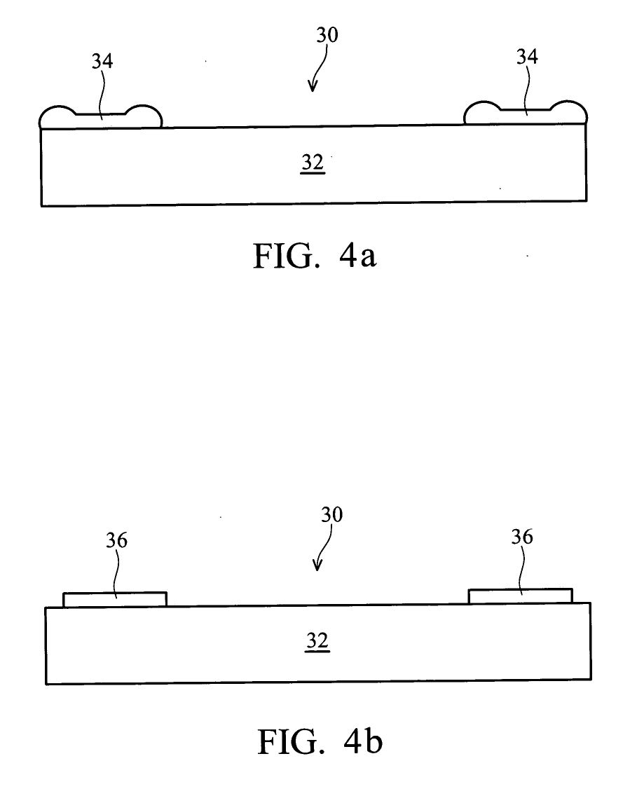

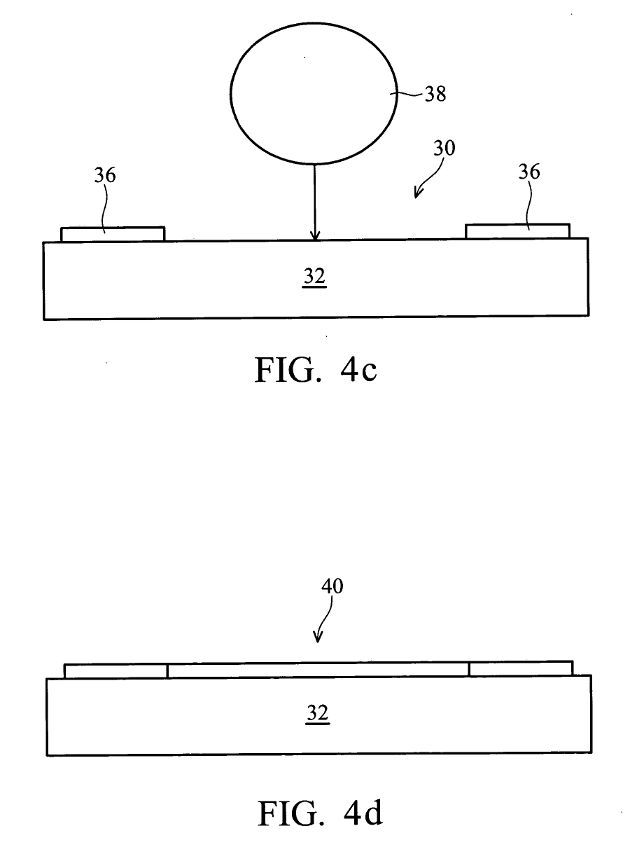

Step 4: A micro pattern 20 is obtained as shown in FIG. 4d.

The first micro fluid layer 16 can be configured in striped, square, circular, elliptical or other shapes according to requirements.

In FIGS. 4a to 4d, a hybrid method combining droplet lithography and micro-fluidic deposition is described, which can be applied to the production of color filters. The hybrid method comprises the following steps:

Step 1: A first micro fluid layer 34 (referred to as a boundary matrix) is formed on a substrate 32. A gap 30 with a predetermined dimension is formed in the first micro fluid layer 34 as shown in FIG. 4a. In general, the first micro fluid layer 34 is a photo resist with thickness ranging from several hundreds of nanometers to several micrometers.

Step 2: The first micro fluid layer 34 is exposed to a light, such as I-line 365 nm/5 mW mercury light, via a pattern mask to obtain a micro pattern 36 as shown in FIG. 4b.

Step 3: Another micro droplet 38 is deposited on the gap 30 as shown in FIG. 4c.

Step 4: When the micro droplet 38 is solidified, a micro pattern 40 is obtained.

The first micro fluid layer 34 can be configured in striped, square, circular, elliptical or other shapes according to requirements.

The described method limits dimensions of the micro pattern 40. In other words, the described method determines the diameter and height of the micro pattern 40 for a micro droplet of certain volume. If the dimensions of the micro pattern are intended to be increased, the described method is obviously incapable of accomplishing the task.

The micro fluid comprises solid content and solvent. Provided that the solid content is s %, the solvent is 100%-s %. Under this condition, although the micro droplet has a constant diameter, the final volume of the droplet (solidified volume) is decreased to V×s %. For example, if a micro droplet of volume V has 10% solid content (10% photo resist, i.e. s=10%) and 90% solvent (PGMEA, i.e. 100%-10%=90%), the solidified volume is decreased to be V×10%.

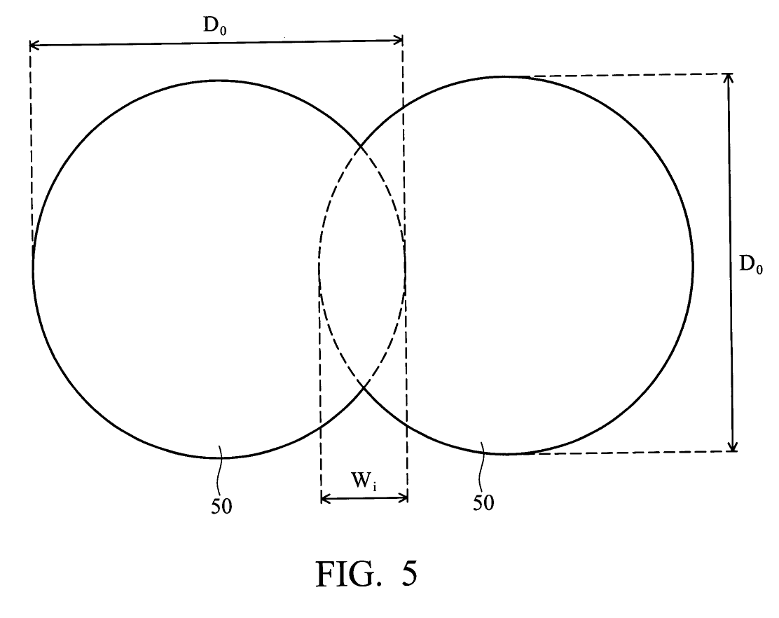

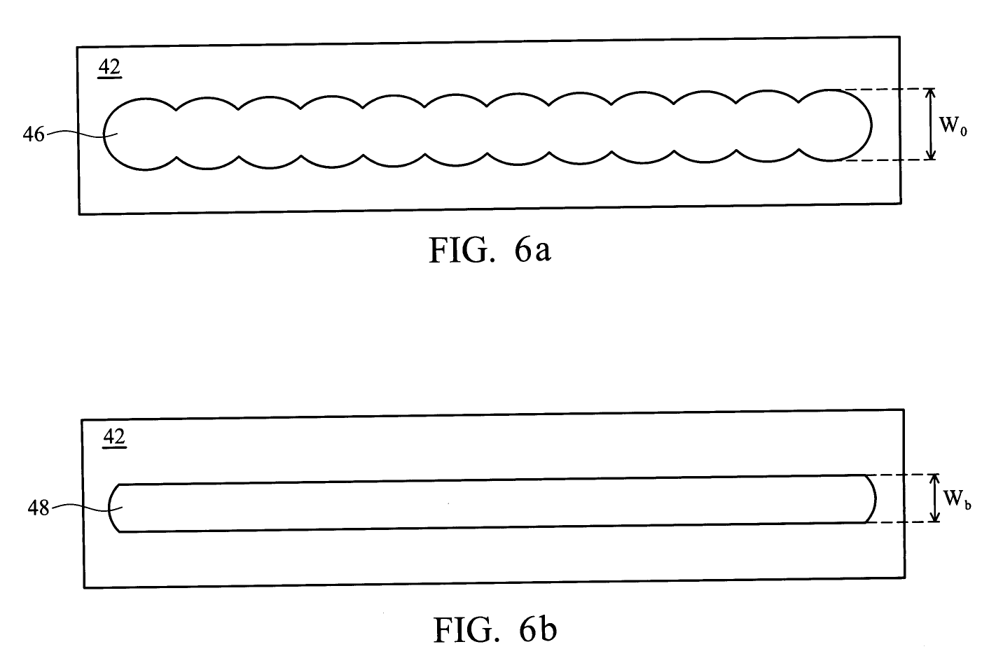

FIG. 5 depicts a pattern formed by dual drops. A pair of drops 50 with diameter of D₀ partially overlaps each other to form a wider micro pattern, and the overlap width is Wᵢ. In this way, a wider micro pattern is obtained by overlapping micro droplets. FIGS. 6a and 6b depict a stacking micro-fluidic deposition (SMD) method. A clean substrate 42 is provided. A plurality of micro drops is deposited on the substrate 42 by micro-fluidic deposition method to form a first micro fluid layer 46 of width W₀. In general, the first micro fluid layer 46 is a hydrophilic photo resist with thickness of several hundreds nanometers to several micrometers. The first micro fluid layer 46 is exposed to light, such as I-line 365 nm/5 mW mercury light, via a pattern mask to obtain a micro pattern 48 of width W_{b}. The width W₀ is larger than W_{b} as indicated by Eq. 1.

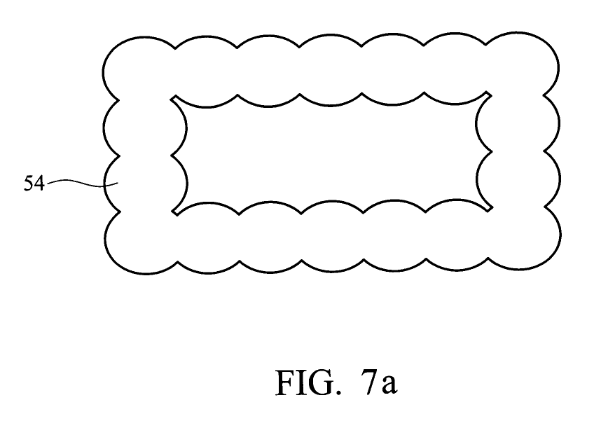

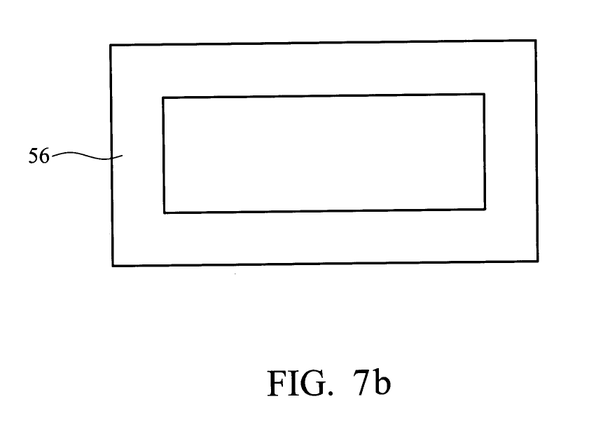

FIGS. 7a and 7b depict another rectangular micro pattern fabricated by the described SMD method. A rectangular first micro fluid layer (boundary matrix film) 54 is formed. The first micro fluid layer 54 is exposed to light via a pattern mask to obtain a micro pattern 56. The micro pattern 56 can be striped, rectangular, circular, elliptical or other shape according to requirements.

The deposition of micro droplets in the SMD method is not limited to a single direction and a single droplet; multiple direction stacking or multiple droplet stacking can also be applied.

The described LP method or LP plus SMD method can be applied to form one dimensional or two dimensional micro patterns (boundary matrix, BM) to produce color filters. To produce color filters, a BM-less method can also be applied. The BM-less method is described as follows.

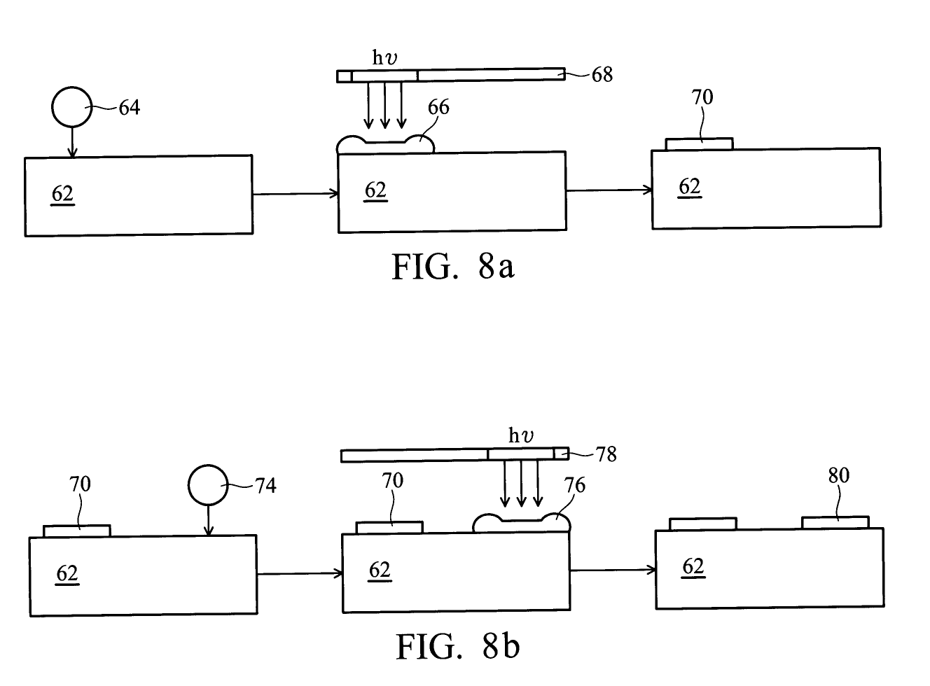

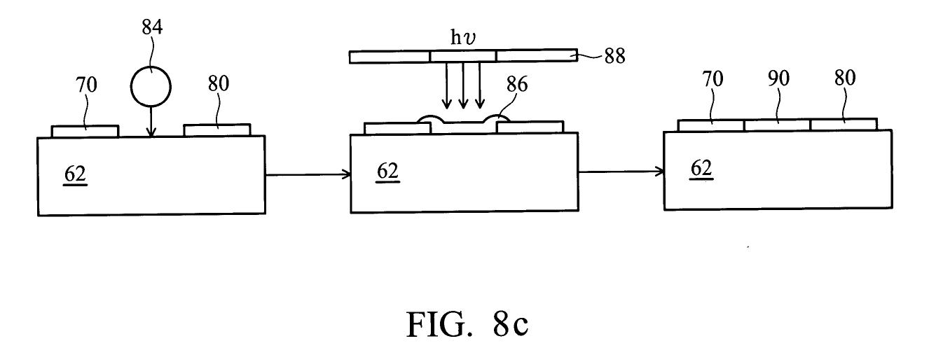

FIGS. 8a, 8b and 8c depict a method of fabricating BM-less color filters employing interlaced deposition. The deposition satisfying Eq. 1 and Eq. 2 as described above is applied. In this method, however, droplets of three colors are alternatively deposited three times and in three positions. In the first deposition, first micro droplets of a first color, such as blue, are deposited in two positions separated by a distance twice as wide as W_{b} on a substrate 62 to form a first micro fluid layer 66. The first micro fluid layer 66 is exposed to a light, such as I-line 365 nm/5 mW mercury light, via a pattern mask to obtain a micro pattern 70 of the first color. The distance twice as wide as W_{b} is prepared for the next deposition for micro droplets of the other two different colors.

In the second deposition, second micro droplets 74 of a second color, such as red, are deposited in two positions separated by a distance twice as wide as W_{b} on the substrate 62 to form a second micro fluid layer 76. The second micro fluid layer 76 is exposed to light via a pattern mask 78 to obtain a micro pattern 80 of the second color. Finally, in the third deposition, third micro droplets 84 of a third color, such as green, are deposited on the substrate 62 to form a third micro fluid layer 86. The third micro fluid layer 86 is exposed to light via a pattern mask 88 to obtain a micro pattern 90 of the third color. A color filter of three colors is accomplished. A certain time must elapse between the two depositions to ensure solidification of the micro droplets.

Although three depositions are described in the embodiment, it is not limited thereto. Two depositions, four depositions, five depositions or more depositions can also be applied. The more depositions used, the less interference between two deposition occurs, but more time is needed to accomplish the depositions.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of forming a micro pattern, comprising the following steps:
providing a substrate;
forming a first micro-fluid layer of photo resistant material on the substrate;
providing a first photo mask; and
exposing the first micro-fluid layer to illuminate via the first photo mask to form a micro pattern.

2. The method of forming a micro pattern as claimed in claim 1, wherein the dimensions of the first micro-fluid layer are larger than that of the micro pattern.

3. The method of forming a micro pattern as claimed in claim 1 further comprising the steps of forming a gap in the first micro-fluid layer; forming a second micro-fluid layer of photo resistant material in the gap; providing a second photo mask; and exposing the second micro-fluid layer to illuminate via the second photo mask.

4. The method of forming a micro pattern as claimed in claim 3, wherein the dimensions of the first micro-fluid layer are larger than that of the micro pattern.

5. The method of forming a micro pattern as claimed in claim 1, wherein the first micro-fluid layer is configured in a line pattern by continuously disposing a plurality of partially overlapping micro-fluid drops on the substrate.

6. The method of forming a micro pattern as claimed in claim 5, wherein the dimensions of the first micro-fluid layer are larger than that of the micro pattern.

7. The method of forming a micro pattern as claimed in claim 1, wherein the first micro-fluid layer is configured in a frame pattern by continuously disposing a plurality of micro-fluid drops partially overlapping each other on the substrate.

8. The method of forming a micro pattern as claimed in claim 7, wherein the dimensions of the first micro-fluid layer are larger than that of the micro pattern.

9. A method of forming a micro pattern, comprising the following steps:
providing a substrate;
forming a plurality of micro-fluid layers corresponding to various photo resistant materials with different colors in different positions on the substrate;
providing a photo mask; and
exposing the micro-fluid layers to illuminate via the photo mask to form micro patterns.

10. A method of forming a micro pattern as claimed in claim 9, wherein the micro-fluid layers are alternatively disposed on the substrate.

11. A method of forming a micro pattern as claimed in claim 9, wherein the dimensions of the micro-fluid layers are larger than that of the micro pattern.
